(19) United States
(12) Patent Application Publication
(10) Pub. No.: US 2018/0135175 A1
(43) Pub. Date: May 17, 2018

(54) FILM FORMING APPARATUS

(71) Applicant: NUFLARE TECHNOLOGY, INC., Yokohama-shi (JP)

(72) Inventors: Kunihiko SUZUKI, Sunto Shizuoka (JP); Naohisa IKEYA, Hiratsuka Kanagawa (JP); Masayoshi YAJIMA, Ashigarakami Kanagawa (JP); Kazukuni HARA, Kariya Aichi (JP); Hiroaki FUJIBAYASHI, Kariya Aichi (JP); Hideki MATSUURA, Kariya Aichi (JP); Katsumi SUZUKI, Nagakute Aichi (JP)

(21) Appl. No.: 15/814,172

(22) Filed: Nov. 15, 2017

(30) Foreign Application Priority Data
Nov. 16, 2016 (JP) 2016-223561

(51) Int. Cl. C23C 16/455; C23C 16/46; C23C 16/52

(52) U.S. Cl. CPC C23C 16/45563; C23C 16/52; C23C 16/46

(57) ABSTRACT

A film forming apparatus according to an embodiment includes: a film forming chamber capable of housing a substrate therein; a gas supplier located in an upper part of the film forming chamber and having a plurality of nozzles supplying gases onto a film forming face of the substrate; a heater configured to heat the substrate; and a first protection cover having a plurality of opening parts at positions corresponding to the nozzles of the gas supplier, respectively.

### CROSS REFERENCE TO RELATED APPLICATIONS

This application is based upon and claims the benefit of priority from the prior Japanese Patent Application No. 2016-223561, filed on Nov. 16, 2016, the entire contents of which are incorporated herein by reference.

### FIELD

The embodiments of the present invention relate to a film forming apparatus.

### BACKGROUND

An epitaxial growth technique that enables to form a film by vapor-depositing a single crystal thin film on a substrate is conventionally used at a manufacturing step of a semiconductor element that requires a crystal film with a relatively large thickness, as a power device such as an IGBT (Insulated Gate Bipolar Transistor).

In a film forming apparatus used for the epitaxial growth technique, a substrate is placed inside a film forming chamber that is kept at a normal pressure or a reduced pressure and a source gas and a doping gas are supplied into the film forming chamber while the substrate is rotated and heated. Accordingly, a pyrolytic reaction and a hydrogen reduction reaction of the source gas occur on the surface of the substrate and an epitaxial film as a coating is formed on the substrate.

The source gas and the doping gas are introduced from a gas supplier that is provided in an upper part of the film forming apparatus. However, if the source gas or the doping gas stays near a supply port of the gas supplier and is heated, a source, a dopant, or a reaction product adheres to the surface of the gas supplier. If the source, the dopant, or the reaction product having adhered to the gas supplier becomes particles and falls on the substrate, a defect may occur. Furthermore, the dopant or the reaction product having adhered to the gas supplier gasifies in the film forming chamber even when the gases in the film forming chamber are discharged or the film forming chamber is purged. In this case, discharge of the gases or purge of the film forming chamber takes a long time.

### SUMMARY

A film forming apparatus according to an embodiment includes: a film forming chamber capable of housing a substrate therein; a gas supplier located in an upper part of the film forming chamber and having a plurality of nozzles supplying gases onto a film forming face of the substrate; a heater configured to heat the substrate; and a first protection cover having a plurality of opening parts at positions corresponding to the nozzles of the gas supplier, respectively.

The film forming chamber may have a temperature-increase suppression region under the gas supplier, in which a temperature increase of the gases is suppressed, and the apparatus may further include a second protection cover covering a first sidewall part of the film forming chamber around the temperature-increase suppression region.

The first sidewall part of the film forming chamber around the temperature-increase suppression region may have an inside diameter smaller than an inside diameter of a second sidewall part of the film forming chamber located below the first sidewall part, and the apparatus may further include a third protection cover covering a stepped portion between the first sidewall part and the second sidewall part.

Each of the first to third protection covers may have a first face exposed in the film forming chamber, and a second face opposed to a portion to be covered, and any of the first to third protection covers may have a shape having concavities and convexities to be fitted in the portion to be covered on the second face

The first protection cover may have a partition plate extending in a supply direction of the gases in the film forming chamber.

The first protection cover may have a plurality of holes located substantially uniformly in a plane of the first protection cover and being smaller than the opening parts.

A plurality of partition plates may be located in a concentric manner.

The apparatus may further include an observation window located on the first sidewall part and enabling observation of the second protection cover.

The apparatus may further include a first cooler located on the first sidewall part of the film forming chamber around the temperature-increase suppression region and configured to cool the temperature-increase suppression region using a refrigerant.

The apparatus may further include a second cooler located on the gas supplier and configured to cool the temperature-increase suppression region using a refrigerant.

The gas supplier may change flow rates of the gases according a distance from a center of the substrate.

### BRIEF DESCRIPTION OF THE DRAWINGS

FIG. 1 is a sectional view illustrating a configuration example of a film forming apparatus 1 according to a first embodiment;

FIG. 2 is a sectional view illustrating a configuration example of the head part 12 of the chamber 10;

FIG. 3 is a perspective view illustrating an internal configuration of the head part 12 of the chamber 10 and the gas supplier 40;

FIG. 4 is a sectional view along a line 4-4 in FIG. 3. Illustrations of the first to third protection covers 110 to 116 are omitted;

FIG. 5 is a plan view illustrating a configuration example of the first protection cover 110;

FIG. 6 is a sectional view illustrating a configuration example of the head part 12 of the chamber 10 according to a second embodiment;

FIG. 7 is a plan view illustrating the first protection cover 110 according to the second embodiment;

FIG. 8 is a sectional view illustrating a configuration example of the head part 12 of the chamber 10 according to a third embodiment;

FIG. 9 is a sectional view illustrating a configuration example of the head part 12 of the chamber 10 according to a fourth embodiment; and

FIG. 10 is a sectional view illustrating a configuration example of the head part 12 of the chamber 10 according to a fifth embodiment.

### DETAILED DESCRIPTION

Embodiments will now be explained with reference to the accompanying drawings. The present invention is not limited to the embodiments.

### First Embodiment

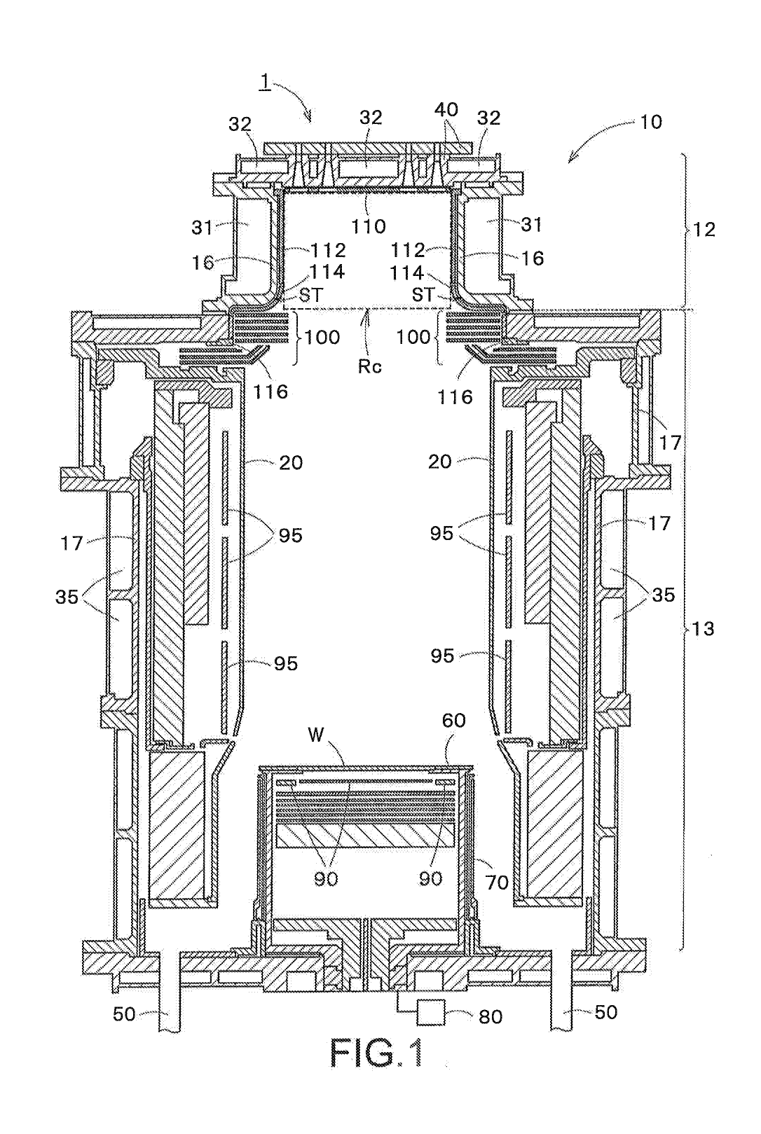

FIG. 1 is a sectional view illustrating a configuration example of a film forming apparatus 1 according to a first embodiment. The film forming apparatus 1 includes a chamber 10, a liner 20, a first cooler 31, a second cooler 32, a third cooler 35, a gas supplier 40, a discharge part 50, a susceptor 60, a support part 70, a rotation mechanism 80, a lower heater 90, an upper heater 85, a reflector 100, and protection covers 110, 112, 114, and 116.

The chamber 10 serving as a film forming chamber can house a substrate W therein and is made of, for example, stainless steel. The inside of the chamber 10 is depressurized by a vacuum pump (not illustrated). The chamber 10 has a head part 12 and a body part 13. The gas supplier 40, the first cooler 31, and the second cooler 32 are provided in the head part 12. A process gas containing a source gas, a carrier gas, and a doping gas supplied from the gas supplier 40 is suppressed in the temperature increase by the first cooler 31 and the second cooler 32 in the inner part of the chamber 10 at the head part 12. The inner part of the head part 12 of the chamber 10 is thus hereinafter referred to as “temperature-increase suppression region Rc”.

The susceptor 60, the rotation mechanism 80, the lower heater 90, the upper heater 95, and the like are placed in the inner part of the chamber 10 at the body part 13. The gases supplied from the gas supplier 40 are heated in the inner part of the body part 13 and react on the surface of the substrate W. Accordingly, a material film is epitaxially grown on the substrate W. The material film is, for example, a SiC film.

The inside diameter of the head part 12 of the chamber 10 is smaller than that of the body part 13. Therefore, the inside diameter of a first sidewall part 16 of the head part 12 is smaller than that of a second sidewall part 17 of the body part 13 and thus a stepped portion ST is provided between the head part 12 and the body part 13. The reflector 100, the liner 20, and the like are provided under the stepped portion ST.

The liner 20 is a hollow tubular member that covers and protects the inner wall of the chamber 10 and is, for example, made of carbon. The liner 20 covers the upper heater 95 to suppress a material film from being formed on the upper heater 95.

The first cooler 31 and the second cooler 32 are provided in the head part 12 of the chamber 10 and, for example, constitute a flow channel of a refrigerant (water, for example). With the refrigerant flowing through the flow channel, the first cooler 31 and the second cooler 32 suppress the temperature increase of the gases in the temperature-increase suppression region Rc. The first cooler 31 and the second cooler 32 are also provided around nozzles of the gas supplier 40. This enables the gases supplied to the temperature-increase suppression region Rc to be cooled. Along therewith, the first cooler 31 and the second cooler 32 prevent the head part 12 of the chamber 10 from being heated by heat from the upper heater 95 or the lower heater 90.

The third cooler 35 is provided in the body part 13 of the chamber 10 and, for example, constitutes a flow channel of a refrigerant (water, for example) similarly to the first cooler 31 and the second cooler 32. However, the third cooler 35 is provided to prevent the body part 13 of the chamber 10 from being heated by heat from the upper heater 95 or the lower heater 90, not to cool the space in the body part 13.

The gas supplier 40 is placed on the top face of the chamber 10 opposed to the surface of the substrate W and has a plurality of nozzles. The gas supplier 40 supplies the source gas, the doping gas, and the carrier gas to the temperature-increase suppression region Rc in the inner part of the chamber 10 through the nozzles.

The discharge part 50 is provided at the bottom of the chamber 10 and discharges the gases having been used for film forming processing out of the chamber 10.

The susceptor 60 is an annular member on which the substrate W can be mounted and is, for example, made of carbon. The support part 70 is a cylindrical member that can support the susceptor 60 and is, for example, made of carbon similarly to the susceptor 60. The support part 70 is connected to the rotation mechanism 80 and is configured to be rotated by the rotation mechanism 80. The support part 70 can rotate the substrate W together with the susceptor 60. The susceptor 60 and the support part 70 can be made of a material having a heat resistance to a temperature equal to or higher than 1700° C., such as SiC (silicon carbide), TaC (tantalum carbide), W (tungsten), or Mo (molybdenum) as well as carbon.

The lower heater 90 is placed below the susceptor 60 and the substrate W and in the inner part of the support part 70. The lower heater 90 heats the substrate W from below. The upper heater 95 is provided along the side face of the body part 13 of the chamber 10 and heats the inner part of the body part 13. The upper heater 95 is placed below the stepped portion ST of the chamber 10 so as not to directly heat the temperature-increase suppression region Rc. While the rotation mechanism 80 rotates the substrate W at a high speed such as 900 rpm or faster, the lower heater 90 and the upper heater 95 heat the substrate W to a high temperature equal to or higher than 1500° C. In this way, the substrate W can be heated uniformly.

The reflector 100 is provided between the head part 12 and the body part 13 in the chamber 10 and is, for example, made of carbon. The reflector 100 reflects heat from the lower heater 90 and the upper heater 95 downward. The temperature in the temperature-increase suppression region Rc is thus prevented from being excessively increased due to heat from the lower heater 90 and the upper heater 95. For example, the reflector 100 functions to cause the temperature in the temperature-increase suppression region Rc to be lower than the reaction temperature of the source gas along with the first cooler 31 and the second cooler 32. The reflector 100 can be made of a material having a heat resistance to a temperature equal to or higher than 1700° C., such as SiC (silicon carbide), TaC (tantalum carbide), W (tungsten), or Mo (molybdenum) as well as carbon. Although the reflector 100 can be a single thin plate, the reflector 100 preferably has a structure in which a plurality of thin plates is located away from each other by an appropriate distance to reflect heat efficiently.

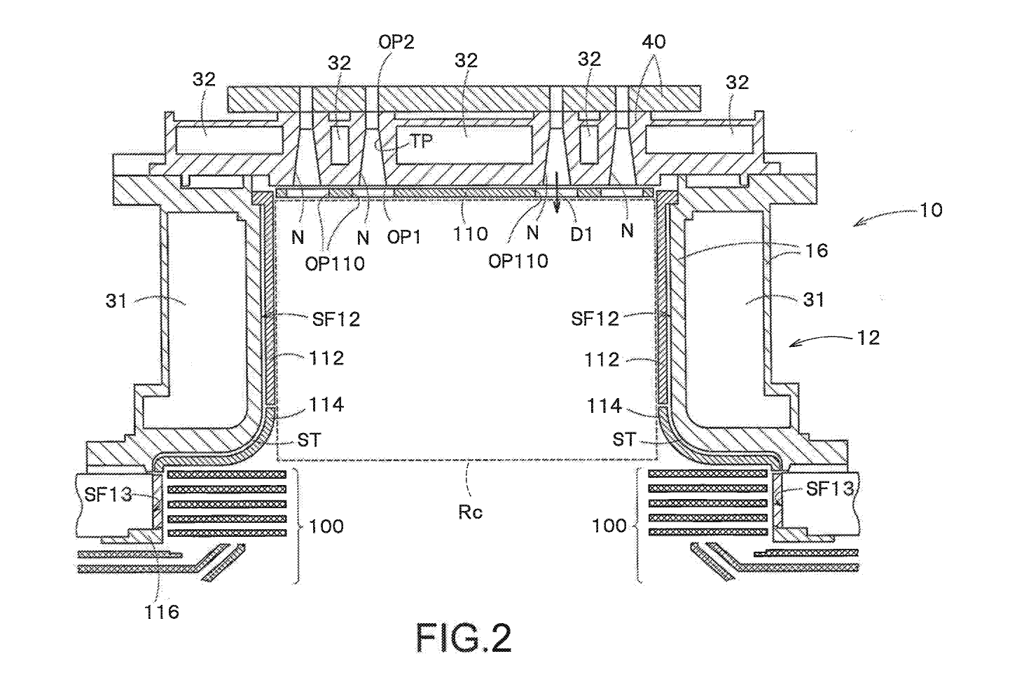

Configurations of the first to third protection covers 110 to 116 are explained with reference to FIG. 2.

FIG. 2 is a sectional view illustrating a configuration example of the head part 12 of the chamber 10. The gas supplier 40 has a plurality of nozzles N. The nozzles N are provided to eject the source gas, the doping gas, and the carrier gas toward the surface of the substrate W placed on the susceptor 60 in the chamber 10 in a direction D1 substantially perpendicular to the surface of the substrate W (that is, in a substantially vertical direction). The nozzles N introduce the source gas, the doping gas, and the carrier gas from outside the chamber 10 to the temperature-increase suppression region Rc in the chamber 10. First opening parts OP1 of the nozzles N are located on an inner side of the chamber 10 and are openings of the nozzles N for ejecting the corresponding gases. Second opening parts OP2 of the nozzles N are located on an outer side of the chamber 10 and are openings of the nozzles N for taking in the corresponding gases.

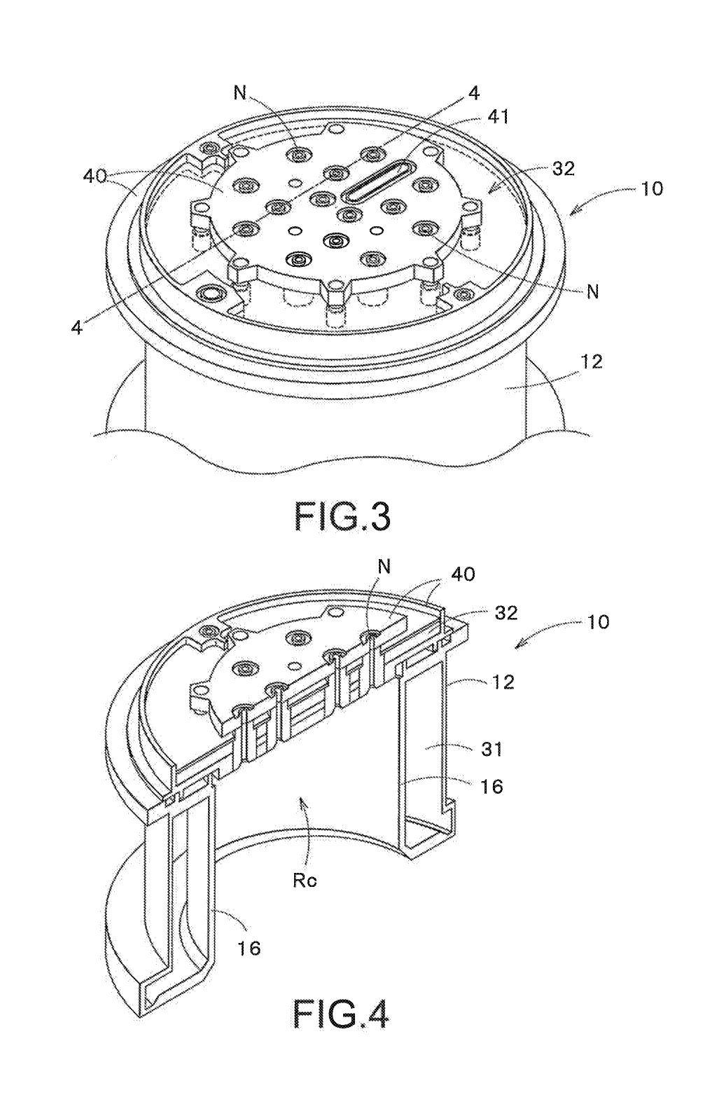

The first protection cover 110 covers the surface of the gas supplier 40 in the chamber 10. The first protection cover 110 has a substantially circular planar shape to correspond to the gas supplier 40 and the substrate W as illustrated in FIG. 3 and is made of, for example, a material having a high heat resistance such as quartz. The first protection cover 110 has a plurality of opening parts OP110 at positions corresponding to the nozzles N, respectively. The opening parts OP110 have a size equal to or larger than the size of the first opening parts OP1 of the nozzles N. Accordingly, the first protection cover 110 does not block the gases ejected from the nozzles N.

The second protection cover 112 covers the first sidewall part 16 of the head part 12 of the chamber 10. The second protection cover 112 has a cylindrical shape and is made of, for example, a highly heat-resistant material such as quartz.

The third protection covers 114 and 116 cover the stepped portion ST between the first sidewall part 16 and the second sidewall part 17. The stepped portion ST has a rounded shape portion from the first sidewall part 16 to the second sidewall part 17. The protection cover 114 is formed in a curved manner along the rounded shape to cover the rounded shape of the stepped portion ST. The protection cover 16 is provided between the reflector 100 and the inner wall of the chamber 10. The third protection covers 114 and 116 are also made of, for example, a highly heat-resistant material such as quartz. The first to third protection covers 110 to 116 can suppress adhesion of a material film, a dopant, or a reaction product to the inner wall of the head part 12 of the chamber 10.

The chamber 10 has the temperature-increase suppression region Rc under the gas supplier 40, in which the temperature increase of the gases is suppressed. The temperature-increase suppression region Rc is an internal space of the head part 12 of the chamber 10 and is provided to suppress the temperature increase of the gases introduced from the nozzles N. The first cooler 31 is provided on the first sidewall part 16 of the chamber 10 around the temperature-increase suppression region Rc. The first cooler 31 uses a refrigerant (water, for example) to suppress the temperature increase in the temperature-increase suppression region Rc via the first sidewall part 16. The second cooler 32 is further provided in the gas supplier 40 located in the upper part of the chamber 10. The second cooler 32 also uses a refrigerant (water, for example) to cool the gases to be supplied to the temperature-increase suppression region Rc via the gas supplier 40. The second cooler 32 is provided around the nozzles N and cools also the gases passing through the nozzles N.

Accordingly, the temperature increase of the source gas, the doping gas, and the carrier gas is suppressed in the temperature-increase suppression region Rc in the head part 12 of the chamber 10. For example, when a SiC film is to be formed, the gas supplier 40 supplies a silane gas and a propane gas as the source gas into the chamber 10. For example, when a P-type SiC film is to be formed, the gas supplier 40 supplies a TMA (Tri-Methyl-Aluminum) gas as the doping gas into the chamber 10. Hydrogen or argon is used, for example, as the carrier gas. The temperature increase is suppressed to cause the temperature in the temperature-increase suppression region Rc to be lower than the reaction temperature (400° C., for example) of the silane gas and the propane gas. Accordingly, adhesion of a material film such as a SiC film to the inner wall of the head part 12 of the chamber 10 or the inner wall of the gas supplier 40 can be suppressed. The temperature increase suppression and cooling include also suppression in the degree of the temperature increase (the increase ratio) of the gases, as well as reduction in the temperature of the gases. Therefore, even if the gas temperature increases in the temperature-increase suppression region Rc, it is adequate when the temperature increase ratio is lower than that in a case where the temperature-increase suppression region Rc is not provided.

Meanwhile, for example, the lower heater 90 and the upper heater 95 heat the substrate W to a high temperature equal to or higher than 1500° C. The gas supplier 40 supplies the silane gas, the propane gas, and the TMA gas to the surface of the heated substrate W. Accordingly, the silane gas and the propane gas react on the surface of the substrate W and a SiC film is epitaxially grown on the surface of the substrate W. At this time, TMA is doped as a dopant into the SiC film, whereby a P-type SIC film is formed.

FIG. 3 is a perspective view illustrating an internal configuration of the head part 12 of the chamber 10 and the gas supplier 40. FIG. 4 is a sectional view along a line 4-4 in FIG. 3. Illustrations of the first to third protection covers 110 to 116 are omitted.

As illustrated in FIG. 3, the gas supplier 40 includes the nozzles N. The second cooler 32 is provided around the nozzles N in the gas supplier 40. The second cooler 32 has a space or a flow channel to enable a refrigerant such as water to be stored therein or flow therethrough. The gas supplier 40 has also a temperature measuring window 41 to measure the temperature of the substrate W, as well as the nozzles N. A radiation thermometer (not illustrated) is placed above the temperature measuring window 41 and the radiation thermometer measures a surface temperature of the substrate W through the temperature measuring window 41. Temperature data of the substrate W is fed back to the lower heater 90 and the upper heater 95 to enable the substrate W to be kept at a desired temperature.

As illustrated in FIG. 4, the first cooler 31 is provided on the first sidewall part 16 of the head part 12 of the chamber 10. The first cooler 31 has a space or a flow channel to enable a refrigerant such as water to be stored therein or flow therethrough.

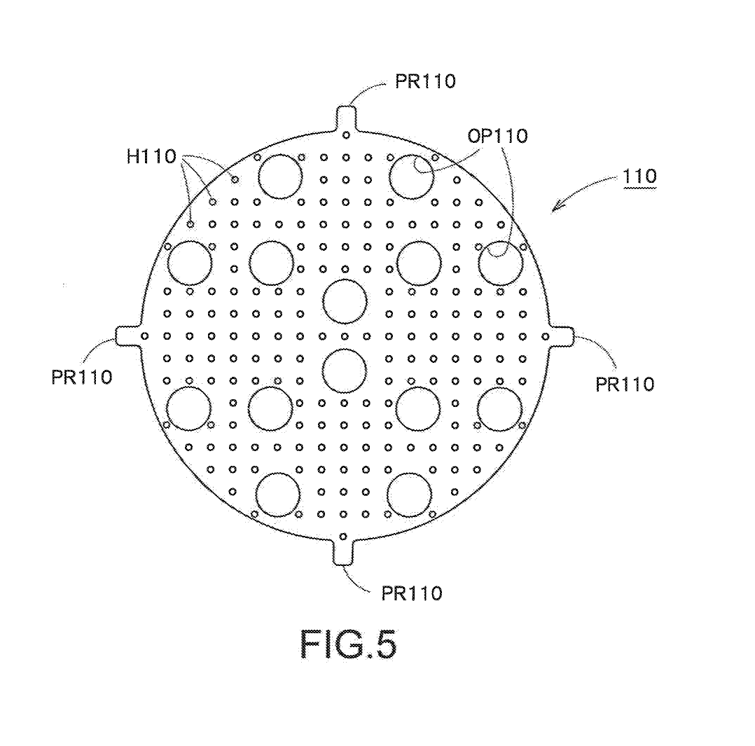

FIG. 5 is a plan view illustrating a configuration example of the first protection cover 110. The protection cover 110 has a substantially circular shape and has the opening parts OP110. The opening parts OP110 are provided to correspond to the nozzles N of the gas supplier 40, respectively. The first protection cover 110 further has a plurality of holes H110 smaller than the opening parts OP110. The holes H110 are provided substantially uniformly in a plane of the first protection cover 110 and, for example, can straighten a periphery purge gas. Protrusions PR110 are provided on the periphery of the first protection cover 110. The protrusions PR110 are supported by the second protection cover 112 or the first sidewall part 16 of the chamber 10 and are provided to fix the first protection cover 110 just under the gas supplier 40.

As described above, the film forming apparatus 1 according to the present embodiment includes the first protection cover 110 that covers the surface of the gas supplier 40 in the chamber 10 and has the opening parts OP110 at the positions corresponding to the nozzles N. Accordingly, it is possible to suppress adhesion of a reaction product (including a dopant) to the inner wall of the gas supplier 40 and protect the gas supplier 40 without interfering with supply of the gases from the gas supplier 40.

The film forming apparatus 1 further includes the second protection cover 112 that covers the first sidewall part 16 of the chamber 10 around the temperature-increase suppression region Rc. Therefore, adhesion of a reaction product (including a dopant) to the inner wall of the chamber 10 can be suppressed and the first sidewall part 16 can be protected.

The film forming apparatus 1 further includes the third protection covers 114 and 116 that cover the stepped portion ST. Accordingly, adhesion of a reaction product (including a dopant) to the stepped portion ST of the inner wall of the chamber 10 can be suppressed and the stepped portion ST can be protected.

The temperature increase in the temperature-increase suppression region Rc just under the gas supplier 40 is suppressed by the first cooler 31 and the second cooler 32. For example, the temperature-increase suppression region Rc is cooled to a temperature equal to or lower than the reaction temperature (400° C., for example) of the source gas. Therefore, the source gas and the doping gas become less likely to react in the temperature-increase suppression region Rc. Accordingly, adhesion of a reaction product (including a dopant) to the inner wall of the head part 12 of the chamber 10 and the inner wall of the gas supplier 40 can be further suppressed.

Meanwhile, the lower heater 90 and the upper heater 95 are provided in the body part 13 to enable the source gas and the doping gas to be rapidly heated. Accordingly, a material film can be epitaxially grown on the surface of the substrate W placed in the body part 13.

A film forming method according to the present embodiment is briefly explained next.

First, a substrate W is carried into the chamber 10 and is placed on the susceptor 60. Next, the substrate W is heated using the upper heater 95 and the lower heater 90 at a rate about 150° C./minute to reach 1500° C. or a higher temperature.

Subsequently, the rotation mechanism 80 rotates the substrate W and the gas supplier 40 supplies the source gas (the silane gas and the propane gas, for example) and the doping gas (the TMA gas, for example) into the chamber 10. A coating (a SIC epitaxial film, for example) is thus formed on the substrate W. At this time, a reaction product (including a dopant) hardly adheres to the inner wall of the head part 12 of the chamber 10 and the gas supplier 40 because the temperature-increase suppression region Rc is provided below the gas supplier 40.

Meanwhile, the lower heater 90 and the upper heater 95 are provided in the body part 13 and heat the source gas and the doping gas to a temperature equal to or higher than 1500° C. Accordingly, a uniform material film can be epitaxially grown on the surface of the substrate W placed in the body part 13.

The temperature in the inner part of the chamber 10 is thereafter lowered and a purge gas is supplied therein. The substrate W is then carried out of the chamber 10.

### Second Embodiment

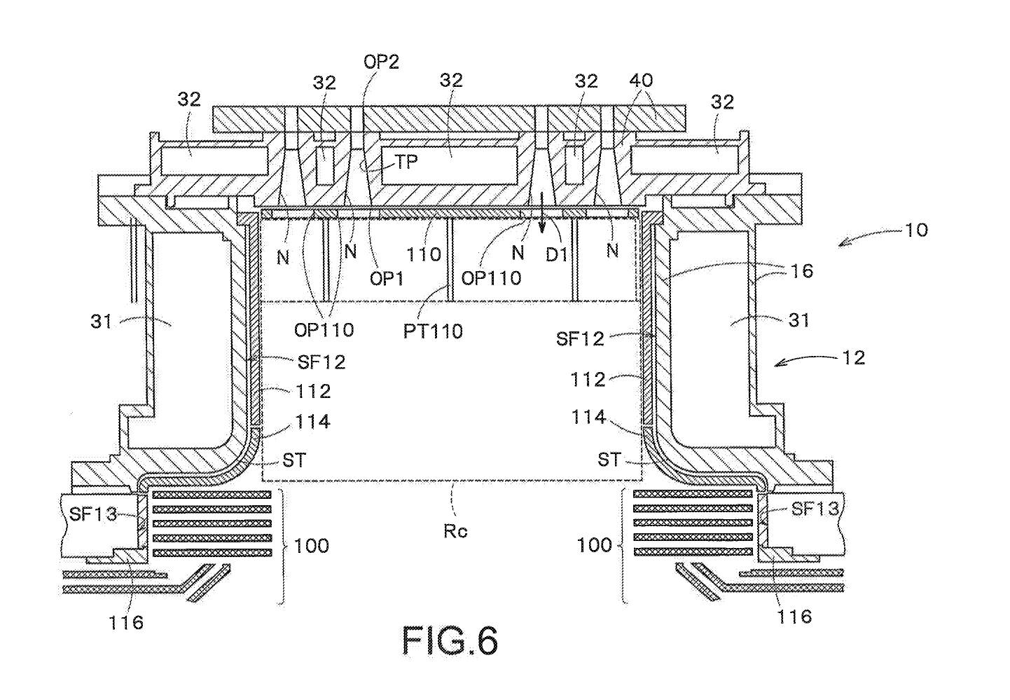

FIG. 6 is a sectional view illustrating a configuration example of the head part 12 of the chamber 10 according to a second embodiment. The second embodiment is different from the first embodiment in that the first protection cover 110 includes partition plates PT110. The partition plates PT110 are provided on the opposite face to an opposed face that is opposed to the gas supplier 40 and extend in a gas supply direction Dl. Although no particularly limited, the length of the partition plates PT110 can be set arbitrarily according to the ejection rate of the gases from the nozzles N. Other configurations of the second embodiment can be identical to corresponding configurations of the first embodiment.

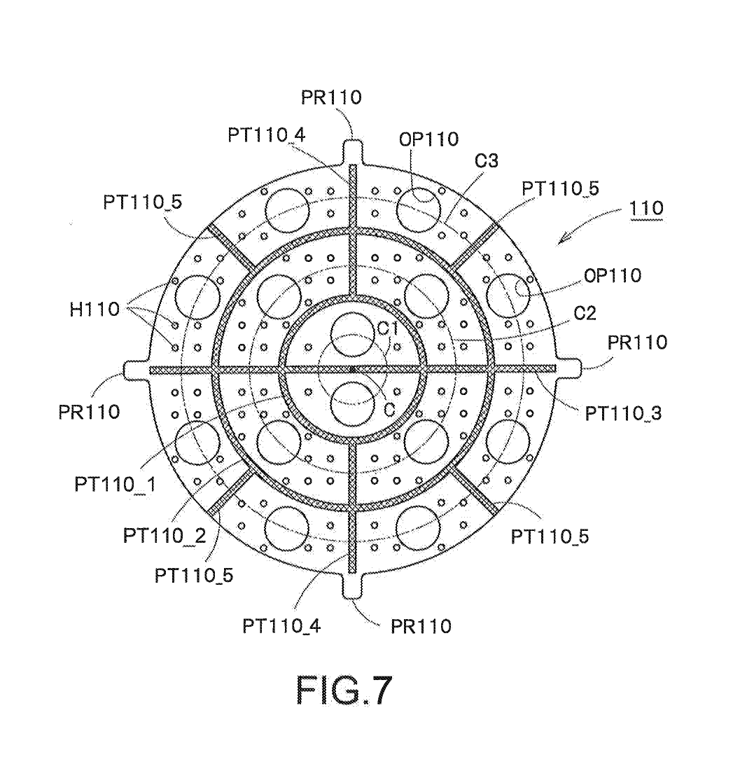

FIG. 7 is a plan view illustrating the first protection cover 110 according to the second embodiment. According to the second embodiment, the partition plates PT110 are provided to separate the opening parts OP110 from each other. Therefore, the partition plates PT110 are provided to be adapted to arrangement of the opening parts OP110.

For example, the opening parts OP110 illustrated in FIG. 7 are provided on concentric circles C1 to C3 to correspond to the nozzles N, respectively. The concentric circles C1 to C3 are concentric circles around a center C and the center C substantially aligns with the center of the substrate W as viewed from above the surface of the substrate W. Among the concentric circles C1 to C3, the concentric circle C1 is the closest to the center C, the concentric circle C2 is the second closest to the center C, and the concentric circle C3 is the farthest from the center C. The concentric circles C1 to C3 are virtual circles and are not actually drawn on the first protection cover 110. The number of the concentric circles is not particularly limited.

For example, two opening parts OP110 are arrayed on the concentric circle C1 substantially uniformly. Four opening parts OP110 are arrayed on the concentric circle C2 substantially uniformly. The distances between adjacent opening parts OP110 on the concentric circle C2 are all equal. Eight opening parts OP110 are arrayed on the concentric circle C3 substantially uniformly. The distances between adjacent opening parts OP110 on the concentric circle C3 are all equal. In this way, the opening parts 110 are arranged on the concentric circles substantially uniformly. It suffices that the arrangement and number of the opening parts OP110 provided on the first protection cover 110 correspond to the arrangement and number of the nozzles N, and the arrangement and number thereof are not particularly limited.

The partition plates PT110 include partition parts PT110_1 and PT110_2 having a concentric shape around the center C and partition parts PT110_3 to PT110_5 extending radially around the center C. The partition part PT110_1 is provided between the concentric circles C1 and C2 and separates the two opening parts OP110 on the concentric circle C1 from the four opening parts OP110 on the concentric circle C2. The partition part PT110_2 is provided between the concentric circles C2 and C3 and separates the four opening parts OP110 on the concentric circle C2 from the eight opening parts OP110 on the concentric circle C3.

The partition part PT110_3 is provided to divide the two opening parts OP110 on the concentric circle C1, the four opening parts OP110 on the concentric circle C2, and the eight opening parts OP110 on the concentric circle C3 into halves, respectively. The partition parts PT110_4 are provided to further divide the two opening parts OP110 on respective portions of the concentric circle C2 divided by the partition part PT110_3 and the four opening parts OP110 on respective portions of the concentric circle C3 divided by the partition part PT110_3 into halves, respectively. The partition parts PT110_5 are provided to further divide the two opening parts OP110 on respective portions of the concentric circuit C3 divided by the partition parts PT110_3 and PT110_4 into halves, respectively.

In this way, the partition plates PT110 are provided to separate the opening parts OP110 from each other. Accordingly, even when the nozzles N corresponding to the opening parts OP110 supply different types of gases, respectively, the partition plates PT110 can suppress the gases from being mixed near the first protection cover 110 or the gas supplier 40. As a result, adhesion of a reaction product (including a dopant) to the first protection cover 110 and the gas supplier 40 can be suppressed. Further, the second embodiment can also obtain effects identical to those of the first embodiment.

In the second embodiment, the partition plates PT110 are provided to separate the opening parts OP110 from each other. However, the partition plates PT110 can be provided for every group of the opening parts OP110. For example, when the same type of gases passes through the group of the opening parts OP110, the partition plates PT110 do not need to be provided between each opening parts OP110 in the group.

When the flow rate of the carrier gas is changed for the nozzles N corresponding to the concentric circles C1, C2, and C3, respectively, the partition plates PT110 can separate the opening parts OP110 by plural parts. That is, when the gas supplier 40 changes the flow rate of the mixture gas according to the distance from the center of the substrate W, the partition plates PT110 can separate the opening parts OP110 by plural parts. This enables the film thickness of a material film formed on the substrate W to be controlled in a concentric manner and adjustment of the film thicknesses is facilitated.

### Third Embodiment

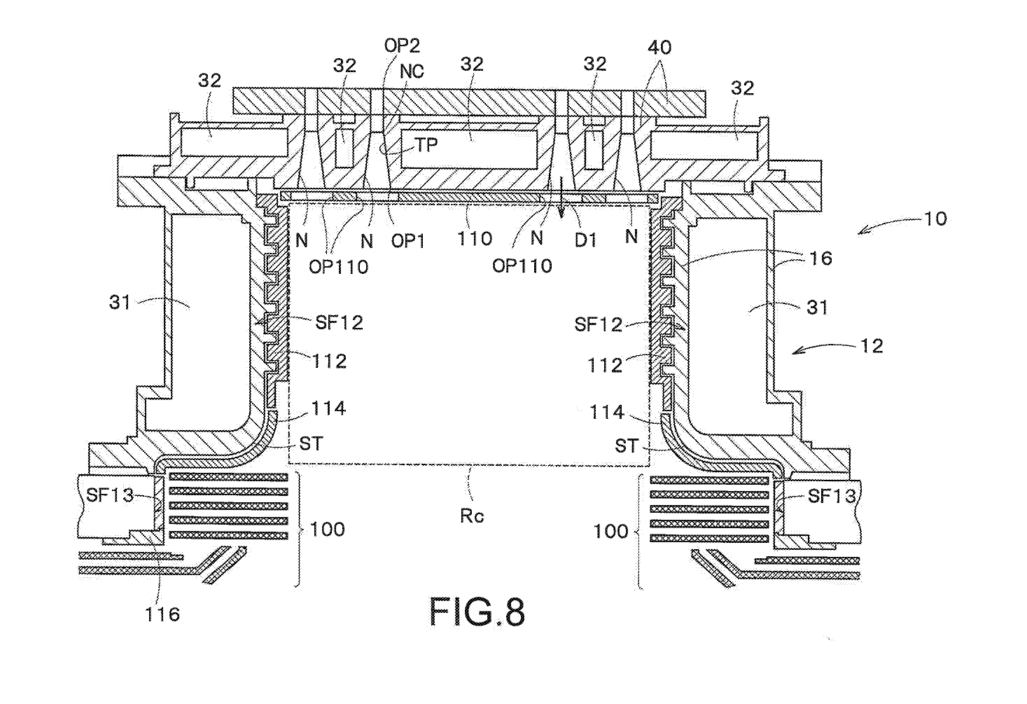

FIG. 8 is a sectional view illustrating a configuration example of the head part 12 of the chamber 10 according to a third embodiment. The second protection cover 112 according to the third embodiment has concavities and convexities on a face opposed to the inner face SF12 of the first sidewall part 16 of the chamber 10. Associated therewith, the inner face SF12 of the first sidewall part 16 of the chamber 10 also has concavities and convexities on a face opposed to the second protection cover 112. The concavities and convexities of the second protection cover 112 and the concavities and convexities of the first sidewall part 16 are alternately fitted in each other to be engaged with each other. That is, the convex portions of the second protection cover 112 are fitted in the concave portions of the first sidewall part 16 and the concave portions of the second protection cover 112 receive the convex portions of the first sidewall part 16, respectively. Accordingly, the opposed area between the second protection cover 112 and the first sidewall part 16 is increased and the temperature increase of the gases in the temperature-increase suppression region Rc can be suppressed by the first cooler 31 more effectively. That is, due to the respective opposed faces of the second protection cover 112 and the first sidewall part 16 formed in the concave and convex shapes, the opposed area therebetween is increased and therefore the cooling effect of the first cooler 31 can be enhanced.

In the third embodiment, the respective opposed faces of the second protection cover 112 and the first sidewall part 16 are formed in the concave and convex shape. However, opposed faces of the first protection cover 110 and the gas supplier 40 and/or opposed faces of the third protection covers 114 and 116 and the inner wall of the chamber 10 can also be similarly formed in a concave and convex shape to be alternately fitted in each other. Due to the concave and convex shape of the opposed faces of the first protection cover 110 and the gas supplier 40, the second cooler 32 can efficiently cool the gases to be supplied to the temperature-increase suppression region Rc. The concave and convex shape of the opposed faces of the third protection covers 114 and 116 and the inner wall of the chamber 10 enables the first cooler 31 to efficiently remove heat of the reflector 100.

### Fourth Embodiment

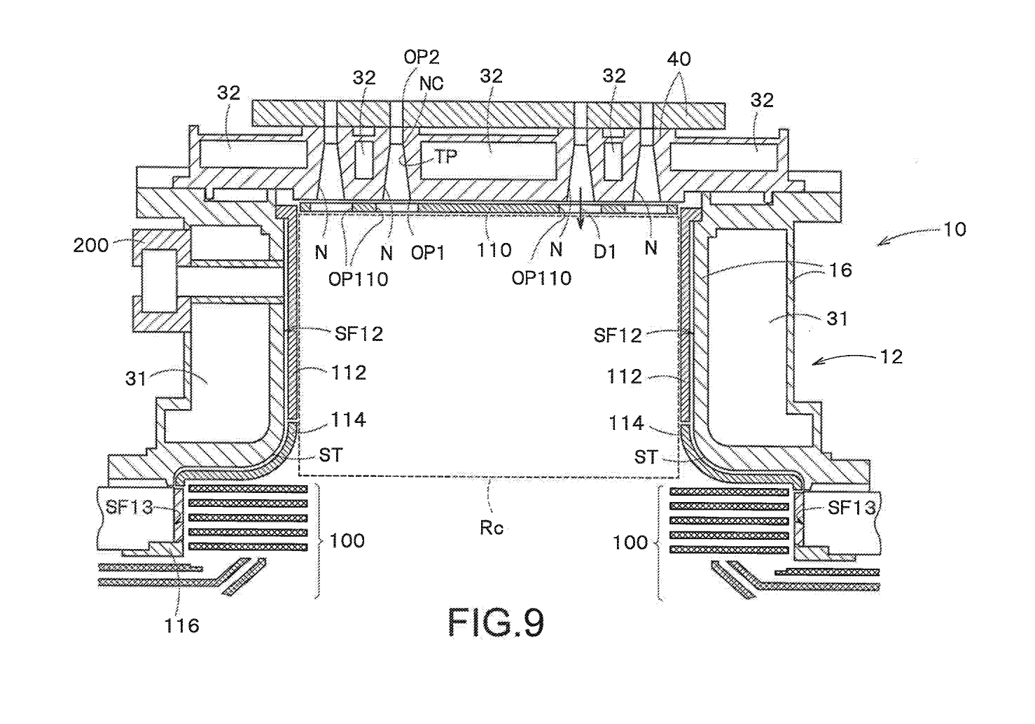

FIG. 9 is a sectional view illustrating a configuration example of the head part 12 of the chamber 10 according to a fourth embodiment. The film forming apparatus 1 according to the fourth embodiment further includes an observation window 200 that is provided on the first sidewall part 16 and that enables observation of the second protection cover 112 and the temperature-increase suppression region Rc. The observation window 200 extends through the first sidewall part 16 and the first cooler 31 to just before the second protection cover 112. An operator can partially observe the second protection cover 112 through the observation window 200. For example, when the second protection cover 112 is made of clear quartz, the operator can recognize whether a reaction product (including a dopant) adheres to the second protection cover 112 by observing the second protection cover 112 through the observation window 200. When the second protection cover 112 is made of clear quartz, the operator can observe the temperature-increase suppression region Rc in the chamber 10 through the observation window 200 and the second protection cover 112.

### Fifth Embodiment

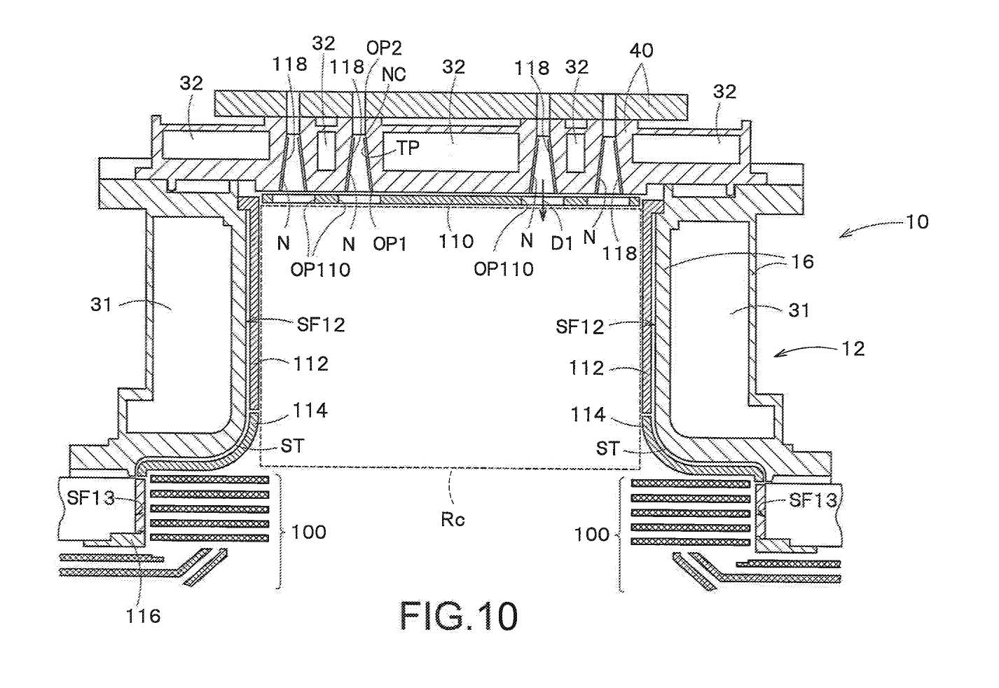

FIG. 10 is a sectional view illustrating a configuration example of the head part 12 of the chamber 10 according to a fifth embodiment. The film forming apparatus 1 according to the fifth embodiment further includes a fourth protection cover 118 on the inner faces of the nozzles N. The fourth protection cover 118 partially covers the inner faces of the nozzles N on the side of the first opening parts OP1.

In the fifth embodiment, at least a part of the side face of each of the nozzles N in a cross-section in the gas supply direction D1 is inclined with respect to the gas supply direction D1 as illustrated in FIG. 10. That is, at least a part of the inner face of each of the nozzles N has a taper. For example, each of the nozzles N has a taper TP on a side face from an intermediate part Nc of the nozzle N to the first opening part OP1. The first opening part OP1 is located on an inner side of the chamber 10 and is an opening of the nozzle N for ejecting the corresponding gas. The second opening part OP2 is located on an outer side of the chamber 10 and is an opening of the nozzle N for taking in the corresponding gas. The intermediate part Nc can be at any position between the first opening part OP1 and the second opening part 0P2.

The fourth protection cover 118 is provided to cover the taper portion of each of the nozzles N near the first opening part OP1. Accordingly, adhesion of a reaction product (including a dopant) to the inner faces of the nozzles N can be suppressed.

The shape of the nozzles N is not particularly limited. Therefore, the nozzles N do not need to have a taper. Alternatively, the nozzles N can have an orifice (not illustrated) in the middle. The fourth protection cover 118 can partially cover the inner face of each of the nozzles N or can entirely cover the inner face. It suffices that the fourth protection cover 118 is formed to be adapted to the shape of the inner face of each of the nozzles N.

Two or more of the first to fifth embodiments described above can be arbitrarily combined with one another. When such a combination is made, the film forming apparatus 1 can obtain effects of plural embodiments.

The first to fifth embodiments can be arbitrarily combined with one another. When such a combination is made, it can obtain effects of the combined embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A film forming apparatus comprising:
a film forming chamber capable of housing a substrate therein;
a gas supplier located in an upper part of the film forming chamber and having a plurality of nozzles supplying gases onto a film forming face of the substrate;
a heater configured to heat the substrate; and
a first protection cover having a plurality of opening parts at positions corresponding to the nozzles of the gas supplier, respectively.

2. The apparatus of claim 1, wherein
the film forming chamber has a temperature-increase suppression region under the gas supplier, in which a temperature increase of the gases is suppressed, and
the apparatus further comprises a second protection cover covering a first sidewall part of the film forming chamber around the temperature-increase suppression region.

3. The apparatus of claim 1, wherein
the first sidewall part of the film forming chamber around the temperature-increase suppression region has an inside diameter smaller than an inside diameter of a second sidewall part of the film forming chamber located below the first sidewall part, and
the apparatus further comprises a third protection cover covering a stepped portion between the first sidewall part and the second sidewall part.

4. The apparatus of claim 2, wherein
the first sidewall part of the film forming chamber around the temperature-increase suppression region has an inside diameter smaller than an inside diameter of a second sidewall part of the film forming chamber located below the first sidewall part, and
the apparatus further comprises a third protection cover covering a stepped portion between the first sidewall part and the second sidewall part.

5. The apparatus of claim 1, wherein
each of the first to third protection covers has a first face exposed in the film forming chamber, and a second face opposed to a portion to be covered, and
any of the first to third protection covers has a shape having a concavity and the convexity to be fitted in the portion to be covered on the second face.

6. The apparatus of claim 2, wherein
each of the first to third protection covers has a first face exposed in the film forming chamber, and a second face opposed to a portion to be covered, and
any of the first to third protection covers has a shape having a concavity and the convexity to be fitted in the portion to be covered on the second face.

7. The apparatus of claim 3, wherein
each of the first to third protection covers has a first face exposed in the film forming chamber, and a second face opposed to a portion to be covered, and
any of the first to third protection covers has a shape having a concavity and the convexity to be fitted in the portion to be covered on the second face.

8. The apparatus of claim 1, wherein the first protection cover has a partition plate extending in a supply direction of the gases in the film forming chamber.

9. The apparatus of claim 2, wherein the first protection cover has a partition plate extending in a supply direction of the gases in the film forming chamber.

10. The apparatus of claim 3, wherein the first protection cover has a partition plate extending in a supply direction of the gases in the film forming chamber.

11. The apparatus of claim 1, wherein the first protection cover has a plurality of holes located substantially uniformly in a plane of the first protection cover and being smaller than the opening parts.

12. The apparatus of claim 8, wherein a plurality of partition plates are located in a concentric manner.

13. The apparatus of claim 2, further comprising an observation window located on the first sidewall part and enabling observation of the second protection cover.

14. The apparatus of claim 2, further comprising a first cooler located on the first sidewall part of the film forming chamber around the temperature-increase suppression region and configured to cool the temperature-increase suppression region using a refrigerant.

15. The apparatus of claim 2, further comprising a second cooler located on the gas supplier and configured to cool the temperature-increase suppression region using a refrigerant.

16. The apparatus of claim 1, wherein the gas supplier changes flow rates of the gases according a distance from a center of the substrate.
